(19) United States
(12) Patent Application Publication
(10) Pub. No.: US 2024/0096877 A1
(43) Pub. Date: Mar. 21, 2024

(54) SEMICONDUCTOR DEVICE AND METHOD FOR MANUFACTURING SEMICONDUCTOR DEVICE

(71) Applicant: Kioxia Corporation, Tokyo (JP)

(72) Inventor: Yuya OMURA, Yokkaichi Mie (JP)

(21) Appl. No.: 18/179,922

(22) Filed: Mar. 7, 2023

(30) Foreign Application Priority Data
Sep. 16, 2022 (JP) 2022-148476

(51) Int. Cl. H01L 27/06; H01L 29/94

(52) U.S. Cl. CPC H01L 27/0629; H01L 29/94

(57) ABSTRACT

According to one embodiment, transistors and a resistance-capacitance element are provided. The transistors each have a gate insulating film with a gate dielectric film and a gate electrode of a metal material. The resistance-capacitance element is provided by stacking a first insulating film, a first conductive layer, a stopper insulating film, a second insulating film, and a second conductive layer on an upper surface of a semiconductor substrate. The second insulating film includes the gate dielectric film like the gate insulating film. The second conductive layer is made of the same metal material as the gate electrode. The first conductive layer is a conductive material having a higher resistance than the second conductive layer.

### CROSS-REFERENCE TO RELATED APPLICATION

This application is based upon and claims the benefit of priority from Japanese Patent Application No. 2022-148476, filed Sep. 16, 2022, the entire contents of which are incorporated herein by reference.

### FIELD

Embodiments described herein relate generally to a semiconductor device and a method for manufacturing a semiconductor device.

### BACKGROUND

In recent years, metal-oxide-semiconductor (MOS) transistors (“transistors”) formed with a gate insulating film of a material having a higher dielectric constant than a silicon oxide film and a gate electrode of a metal material having a lower resistance than polycrystalline silicon have been developed. However, semiconductor devices also include capacitors and resistance elements in addition to transistors. Due to its purpose, the resistance element is desirably made of a high-resistance material.

### BRIEF DESCRIPTION OF THE DRAWINGS

FIG. 1 is a cross-sectional of a semiconductor device according to an embodiment.

FIGS. 2 to 16 are cross-sectional views depicting aspects of a manufacturing process of a semiconductor device according to an embodiment.

FIG. 17 is a cross-sectional view of another semiconductor device according to an embodiment.

FIGS. 18 to 26 are cross-sectional views depicting aspects of a manufacturing process of another semiconductor device according to an embodiment.

### DETAILED DESCRIPTION

Embodiments relate to efficiently manufacturing a MOS transistor, a capacitor, and a resistance element in a semiconductor device, and providing a capacitor and a resistance element in an area-efficient manner in a semiconductor device.

In general, according to one embodiment, a semiconductor device includes a transistor that includes a gate insulating film provided on an upper surface of a semiconductor substrate and having a dielectric film, and a gate electrode made of a metal material and provided on an upper surface of the gate insulating film. The semiconductor device further includes a resistance-capacitance element that includes a first insulating film provided on the upper surface of the semiconductor substrate, a first conductive layer provided on an upper surface of the first insulating film, a second insulating film provided on an upper surface of the first conductive layer, a third insulating film provided on an upper surface of the second insulating film, and a second conductive layer provided on an upper surface of the third insulating film. The third insulating film includes the dielectric film of the gate insulating film. The second conductive layer is made of the same metal material as the gate electrode. The first conductive layer is a conductive material having a higher electrical resistance than the second conductive layer.

A method for manufacturing a semiconductor device according to the present embodiment includes forming a first insulating film on an upper surface of a semiconductor substrate, forming a first conductive film made of a conductive material on an upper surface of the first insulating film, forming a second insulating film made of an insulating material on a portion of an upper surface of the first conductive film, and forming a second conductive film made of the conductive material on an upper surface of the first conductive film as well as on an upper surface of the second insulating film. The method for manufacturing a semiconductor device further includes forming a first trench extending from the upper surface of the second conductive film to a predetermined depth of the semiconductor substrate at a position including a peripheral edge of the second insulating film, and then embedding (filling) the first trench with an element isolation insulating film; processing the second conductive film, the second insulating film, and the first conductive film into a predetermined shape of a resistor wiring or capacitor electrode in a first region of the semiconductor substrate; and processing the second conductive film and the first conductive film into a predetermined shape of a gate electrode in a second region. Furthermore, the method for manufacturing a semiconductor device includes forming sidewalls made of insulating material so as to cover the sidewalls of the processed second conductive film, second insulating film, and first conductive film; forming a second trench inside the sidewalls by removing the conductive material inside the sidewalls using conditions having a high selectivity with respect to the insulating material; forming a dielectric film made of a high-k dielectric material on the inner wall of the second trench; and embedding a third conductive film made of a metal material in the second trench to form the gate electrode and the resistor wiring or capacitor electrode on a surface of the dielectric film.

Hereinafter, certain example embodiments will be described with reference to the drawings.

In the following, for convenience of explanation, a vertical direction from the semiconductor substrate 10 in the drawings may be described using a relative relationship terminology in which the more Z-axis positive direction side is the upward, higher, upper side, direction and vice versa, but the adoption of such terminology does not necessarily correspond to gravitational directions or the like. Also, the drawings are schematic, and, as such, the depicted dimensions, proportions, and the like of each depicted component, element, aspect, and the like are not necessarily the same as those in an actual implementation.

(1. Structure of Semiconductor Device)

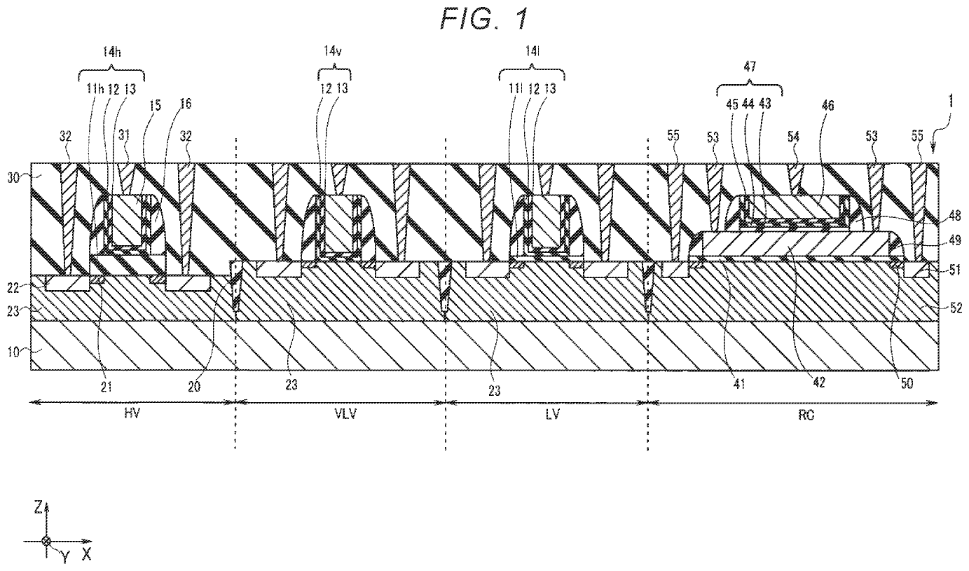

FIG. 1 is a cross-sectional view schematically illustrating the structure of the semiconductor device 1 according to the embodiment. The semiconductor device 1 can be, for example, a peripheral circuit used for controlling a NAND flash memory or the like. The semiconductor device 1 includes, as circuit elements, a high voltage transistor HV, a low voltage transistor LV, a very low voltage transistor VLV, and a resistance-capacitance element RC.

In FIG. 1, the high voltage transistor HV, the very low voltage transistor VLV, the low voltage transistor LV, and a resistance-capacitance element RC are shown in order from the left. The resistance-capacitance element RC is a circuit element that can be used both as a resistance element and as a capacitor. These circuit elements are formed at appropriate and designed positions on the semiconductor substrate 10 and may not always necessarily be formed adjacent to each other as shown in FIG. 1. For the convenience of explanation, FIG. 1 shows these circuit elements located spaced from one another along the X direction.

An element isolation region 20 is formed on the upper surface of the semiconductor substrate 10. The element isolation region 20 is a trench formed from the upper surface of the semiconductor substrate 10 to a predetermined depth. The trench is embedded (filled) with an insulating film such as a silicon oxide film. The element isolation region 20 defines an active region, which is a region in which a circuit element is formed, on the upper surface of the semiconductor substrate 10. Element isolation regions 20 are formed between the adjacent active regions in order to electrically isolate one active region from another one of the active regions. The high voltage transistor HV, the low voltage transistor LV, the very low voltage transistor VLV, and the resistance-capacitance element RC are typically formed in different active regions electrically isolated by element isolation regions 20 from one another.

First, the structure of the high voltage transistor HV will be described. A gate electrode 15 is formed on the semiconductor substrate 10 in the active region with a gate oxide film 11h, an interlayer film 12, and a gate dielectric film 13 interposed therebetween. The gate oxide film 11 and the interlayer film 12 are, for example, silicon oxide films. The gate dielectric film 13 is, for example, an insulating film having a high dielectric constant (“a high-k material”), such as hafnium silicate (HfSiO). A three-layered film of the gate oxide film 11h, the interlayer film 12, and the gate dielectric film 13 configures a gate insulating film 14h of the high voltage transistor HV. The gate electrode 15 is made of, for example, a metal material such as tungsten (W) or aluminum (Al). The interlayer film 12 and the gate dielectric film 13 cover the side surfaces of the gate electrode 15 as well. Further, a sidewall film 16 (also referred to as sidewall 16) covers the outer surface of the interlayer film 12 formed on the side surface of the gate electrode 15, that is, the surface of the interlayer film 12 opposite to the surface in contact with the gate dielectric film 13. The sidewall 16 is, for example, a silicon oxide film.

Lightly doped drain (LDD) regions 21 and source and drain regions 22 are formed in the semiconductor substrate 10 on the right and left sides of the gate electrode 15 in the X direction. For example, if the high voltage transistor HV is an n-type MOS transistor (NMOS transistor), the LDD region 21 is implanted with n-type impurities such as arsenic (As) and phosphorus (P). Impurities such as arsenic (As) and phosphorus (P) are implanted into the source and drain regions 22 and diffused to a predetermined depth. The source and drain regions 22 have a higher impurity concentration than the LDD regions 21 and are formed to a position deeper than the LDD regions 21 from the upper surface of the semiconductor substrate 10. A well diffusion layer 23 is formed in the semiconductor substrate 10 in the active region where the high voltage transistor HV is formed. If the high voltage transistor HV is an NMOS transistor, the well diffusion layer 23 is implanted with impurities such as boron (B) and diffused to a predetermined depth.

An interlayer insulating film 30 covers the upper surface of the gate electrode 15, the sidewall 16, and the source and drain region 22. The interlayer insulating film 30 is, for example, a silicon oxide film. A wiring layer is ultimately formed above the interlayer insulating film 30. A contact plug 31 for electrically connecting the wiring layer and the gate electrode 15 is formed above the gate electrode 15. That is, a potential (voltage) from the wiring layer is supplied to the gate electrode 15 through the contact plug 31. Contact plugs 32 for electrically connecting the wiring layer and the source and drain regions 22 are formed above the source and drain regions 22. That is, a potential from the wiring layer is supplied to the source and drain regions 22 through the contact plugs 32.

In general, the low voltage transistor LV is configured with the same elements as in the high voltage transistor HV except for a gate insulating film 141 being utilized instead of the gate insulating film 14h. A gate insulating film 141 of the low voltage transistor LV is configured with a gate oxide film 111, the interlayer film 12, and the gate dielectric film 13. The gate oxide film 111 is, for example, a silicon oxide film. The thickness of the gate oxide film 111 is less than the thickness of the gate oxide film 11h of the high voltage transistor HV.

In general, the very low voltage transistor VLV is configured with the same elements as those in the high voltage transistor HV except for a gate insulating film 14v being utilized instead of the gate insulating film 14h. The gate insulating film 14v of the very low voltage transistor VLV is configured with the interlayer film 12 and the gate dielectric film 13.

Next, the structure of the resistance-capacitance element RC will be described. In the resistance-capacitance element RC, a first conductive layer 42 is formed on the semiconductor substrate 10 in an active region with a first insulating film 41 interposed therebetween. The first insulating film 41 can be made of the same material (for example, a silicon oxide film) as the gate oxide film 111 and has the same thickness as the gate oxide film 111. The first conductive layer 42 is formed using, for example, polycrystalline silicon (polysilicon). The height of the first conductive layer 42 (that is, the distance along the Z direction from the lower surface of the semiconductor substrate 10 to the upper surface of the first conductive layer 42) is less than the height of the gate electrode 15 (that is, the distance along the Z direction from the lower surface of the semiconductor substrate 10 to the upper surface of the gate electrode 15). For example, the first conductive layer 42 is about half the height of the gate electrode 15.

A second conductive layer 46 is formed on the first conductive layer 42 with a stopper insulating film 43, an interlayer film 44, and a dielectric film 45 interposed therebetween. The stopper insulating film 43 is made of, for example, a silicon oxide film. The interlayer film 44 is made of the same material (for example, silicon oxide film) as the interlayer film 12 and has the same film thickness as the interlayer film 12. The dielectric film 45 is made of the same material as the gate dielectric film 13 (for example, hafnium silicate (HfSiO)) and has the same film thickness as the gate dielectric film 13. The second conductive layer 46 is made of the same material as the gate electrode 15 (for example, tungsten (W) or aluminum (Al)). The width (the dimension in the X direction) of the second conductive layer 46 is less than the width of the first conductive layer 42. That is, the upper surface of the first conductive layer 42 is exposed on the right and left sides of the second conductive layer 46 in the X direction. The height of the second conductive layer 46 is the same as the height of the gate electrode 15. A second insulating film 47 is configured with a three-layered film of the stopper insulating film 43, the interlayer film 44, and the dielectric film 45. The interlayer film 44 and the dielectric film 45 cover the side surfaces of the second conductive layer 46 as well.

A sidewall 48 covers the outer surface of the interlayer film 44 formed on the side surface of the second conductive layer 46, that is, the surface of the interlayer film 44 opposite to the surface in contact with the dielectric film 45. A sidewall 49 is also formed on the side surface of the first conductive layer 42. The sidewalls 48 and 49 are made of the same material as the sidewall 16 (for example, silicon oxide film).

A first impurity region 50 and a second impurity region 51 are formed in the semiconductor substrate 10 on the right and left sides of the first conductive layer 42 in the X direction. The first impurity region 50 is implanted with the same impurity as the LDD region 21 of any one of the high voltage transistor HV, the low voltage transistor LV, and the very low voltage transistor VLV. The second impurity region 51 is implanted with the same impurity as the source and drain region 22 of any one of the high voltage transistor HV, the low voltage transistor LV, and the very low voltage transistor VLV and is diffused to a predetermined depth. A well diffusion layer 52 is formed in the semiconductor substrate 10 in the active region where the resistance-capacitance element RC is formed. The well diffusion layer 52 is implanted with the same impurity as the well diffusion layer 23 of any one of the high voltage transistor HV, the low voltage transistor LV, and the very low voltage transistor VLV and is diffused to a predetermined depth.

The interlayer insulating film 30 covers the upper surface of the first conductive layer 42, the upper surface of the second conductive layer 46, the sidewalls 48 and 49, and the second impurity region 51. The interlayer insulating film 30 is, for example, a silicon oxide film. A wiring layer is ultimately formed above the interlayer insulating film 30. A first contact plug 53 is formed above the first conductive layer 42 to provide electrical connection between the wiring layer and the first conductive layer 42. A second contact plug 54 is formed above the second conductive layer 46 to provide electrical connection between the wiring layer and the second conductive layer 46. A third contact plug 55 is formed above the second impurity region 51 to provide electrical connection between the wiring layer and the second impurity region 51.

The resistance-capacitance element RC has a structure formed by stacking two capacitors. A first-type capacitor (which is the lower positioned capacitor of the two) has the semiconductor substrate 10 as one electrode and the first conductive layer 42 as the other electrode with the first insulating film 41 interposed therebetween. The resistance-capacitance element RC can be used as the first-type capacitor by connecting the third contact plug 55 (which is connected to the second impurity region 51) and the first contact plug 53 (which connected to the first conductive layer 42) to the above-formed wiring layer.

A second-type capacitor (which is the higher positioned capacitor of the two) has the first conductive layer 42 as one electrode and the second conductive layer 46 as the other electrode with the second insulating film 47 therebetween. The resistance-capacitance element RC can be used as the second-type capacitor by connecting the first contact plug 53 (which is connected to the first conductive layer 42) and the second contact plug 54 (which is connected to the second conductive layer 46) to the wiring layer.

Also, the first conductive layer 42 is formed of a material such as polysilicon which generally has a higher resistance than a metal material. Therefore, the first conductive layer 42 can be used as a resistance wiring. The resistance-capacitance element RC can be used as a resistance element (resistor) by connecting two first contact plugs 53 formed on the first conductive layer 42 to the wiring layer. The second conductive layer 46 can also be used as a resistance element. That is, the first conductive layer 42 and the second conductive layer 46 can be used as resistance wiring or capacitance electrodes according to design need. In this manner, the resistance-capacitance element RC can be used as both a capacitor and a resistance element by changing the connection points between the later-formed wiring layer and the first, second, and third contact plugs 53, 54, and 55.

(2. Method for Manufacturing Semiconductor Device)

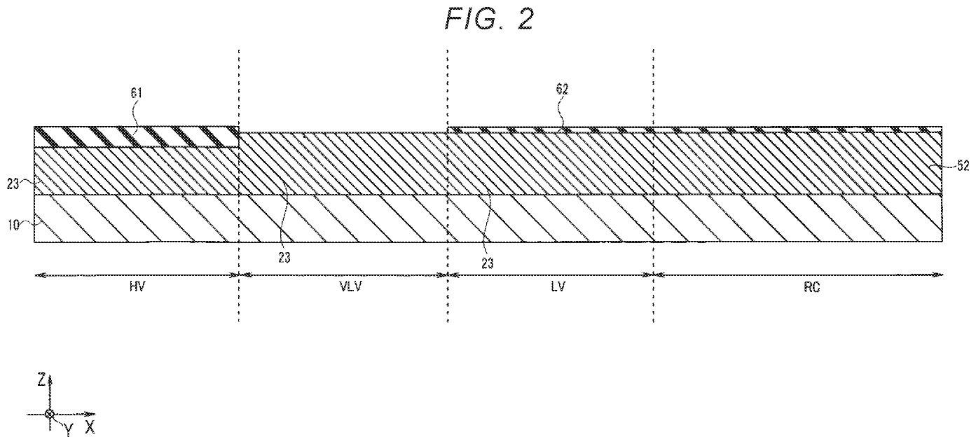

Next, a method for manufacturing the semiconductor device 1 according to an embodiment will be described with reference to FIGS. 2 to 16. FIGS. 2 to 16 are cross-sectional views showing aspects of the manufacturing process of a semiconductor device of an embodiment. First, as shown in FIG. 2, the well diffusion layers 23 and 52 are formed by implanting and diffusing impurities from the upper surface of the semiconductor substrate 10 to a predetermined depth using an ion implantation technique and diffusion technique. In the formation of the well diffusion layer 23, impurities are implanted into the high voltage transistor HV forming region, the low voltage transistor LV forming region, and the very low voltage transistor VLV forming region according to the carriers of each transistor type. In the case of a PMOS transistor whose carriers are holes, n-type impurities such as arsenic (As) or phosphorus (P) are implanted and diffused. In the case of an NMOS transistor in which carriers are electrons, p-type impurities such as boron (B) are implanted and diffused. In the well diffusion layer 52 in the resistance-capacitance element RC, the same impurity as that implanted into the well diffusion layer 23 of any one of the high voltage transistor HV forming region, the low voltage transistor LV forming region, or the very low voltage transistor VLV forming region is implanted.

Subsequently, using a thermal oxidation technique, a silicon oxide film 61 is formed in the high voltage transistor HV forming region. Also, a silicon oxide film 62 is formed in the low voltage transistor LV forming region and in the resistance-capacitance element RC forming region using a thermal oxidation technique. The film thickness of the silicon oxide film 61 is formed thicker than the film thickness of the silicon oxide film 62. The silicon oxide film 61 is processed into the gate insulating film 14h in a later process. The silicon oxide film 62 is processed into the gate insulating film 141 and the first insulating film 41 in a later process.

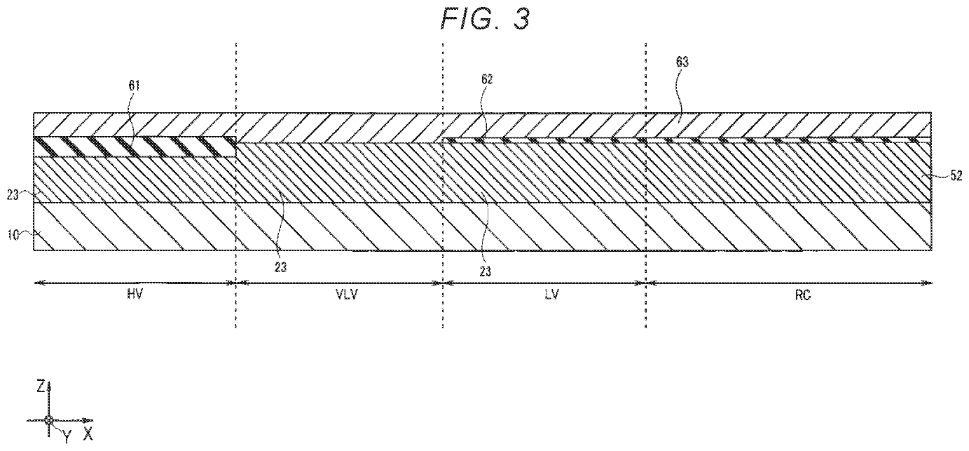

Next, as shown in FIG. 3, a polysilicon film 63 is formed on the entire upper surface of the semiconductor substrate 10 using a chemical vapor deposition (CVD) technique or the like. The polysilicon film 63 in the high voltage transistor HV forming region, the low voltage transistor LV forming region, and the very low voltage transistor VLV forming region can be processed into dummy gates for forming the gate electrodes 15 in a later process. The polysilicon film 63 in the resistance-capacitance element RC forming region is processed into the first conductive layer 42 in a later step. When the first conductive layer 42 is to be used as a resistance element, impurities may be implanted into the polysilicon film 63 using an ion implantation technique or the like in order to adjust the resistance value.

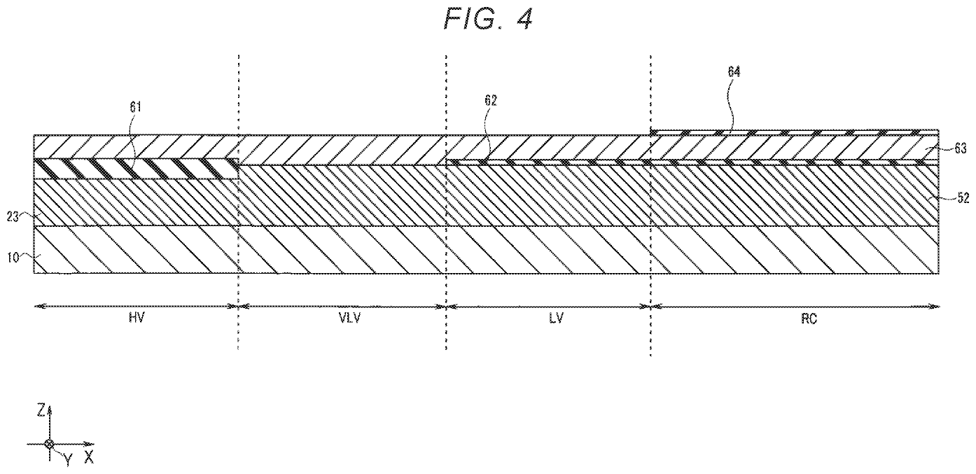

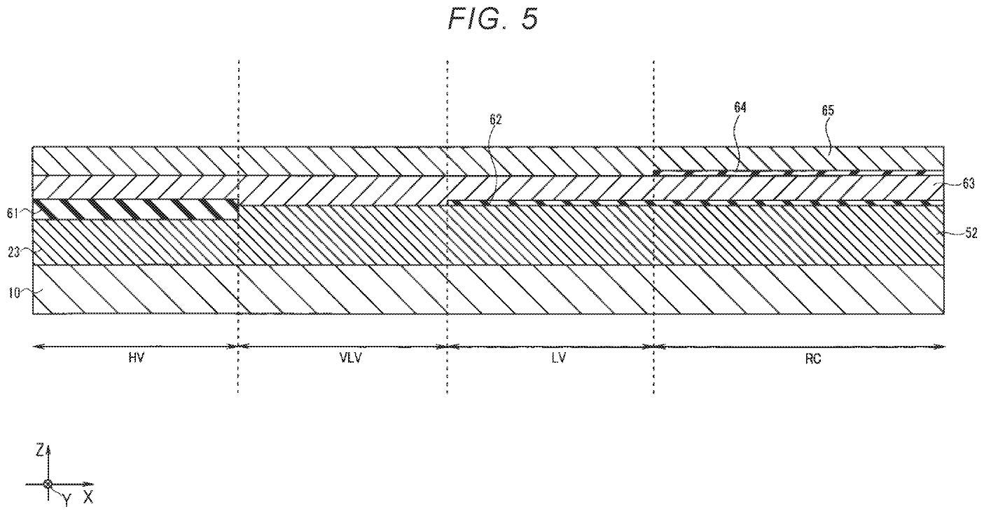

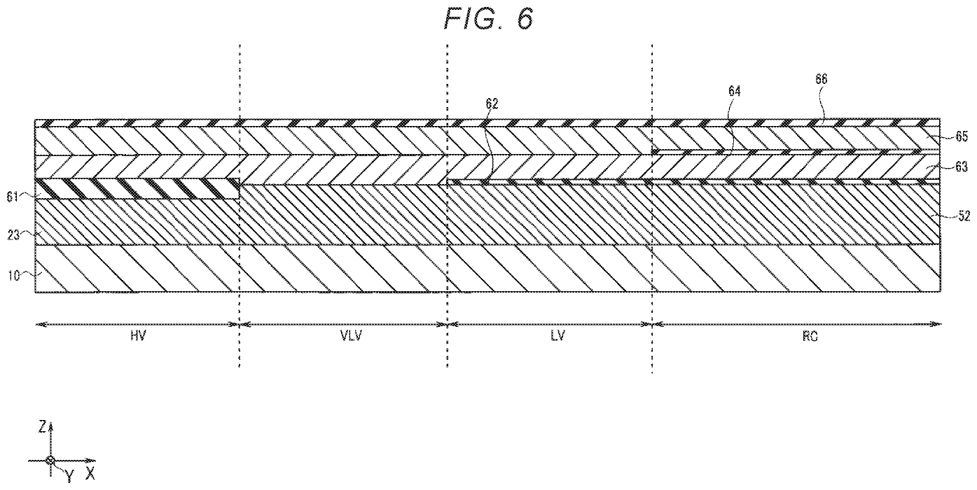

Subsequently, as shown in FIG. 4, a silicon oxide film 64 is formed on the entire upper surface of the semiconductor substrate 10 using a CVD technique. Then, a photolithography technique and an anisotropic etching technique (such as reactive ion etching (RIE)) are used to selectively remove the silicon oxide film 64 other than in the resistance-capacitance element RC forming region. The silicon oxide film 64 formed on the resistance-capacitance element RC forming region functions as the stopper insulating film 43. The stopper insulating film 43 may be a film that is difficult to etch (a film having a high etch selectivity) when etching a polysilicon film 65, which will be described later, and may be formed of a material other than a silicon oxide film. Then, as shown in FIG. 5, the polysilicon film 65 is formed on the entire upper surface of the semiconductor substrate 10 using a CVD technique or the like. The polysilicon film 65 is processed into a dummy gate for forming the gate electrode 15 and the second conductive layer 46 in a later process. Further, as shown in FIG. 6, a silicon nitride film 66 is formed on the upper surface of the polysilicon film 65 using a CVD technique or the like.

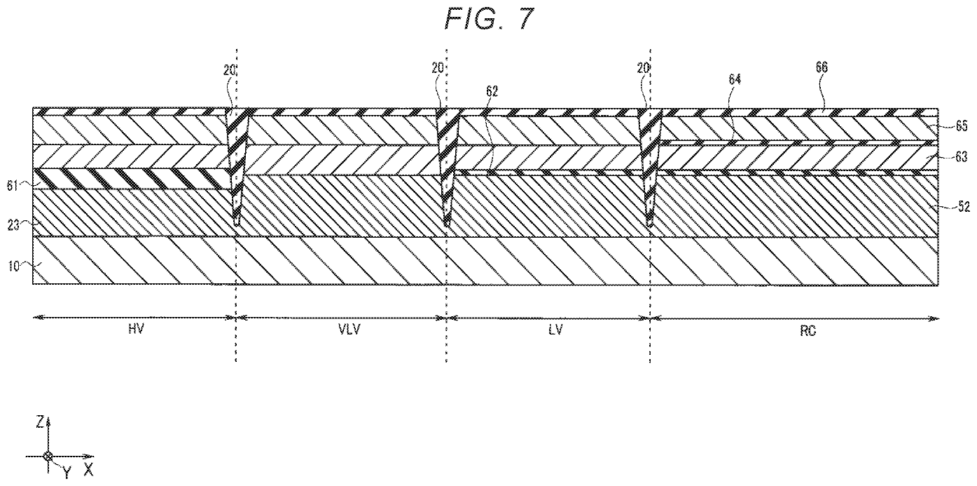

Next, element isolation regions 20 are formed. First, a photolithography technique and an anisotropic etching technique are used to form trenches in the semiconductor substrate 10 between the respective active regions of the high voltage transistor HV, the low voltage transistor LV, the very low voltage transistor VLV, and the resistance-capacitance element RC. Then, a silicon oxide film is formed on the entire upper surface of the semiconductor substrate 10 using a CVD technique or the like. Subsequently, using a chemical mechanical polishing (CMP) technique or the like, excess silicon oxide film can be removed using the silicon nitride film 66 as a stopper so as to permit removal of any portion of silicon oxide film above the level of the silicon nitride film 66. By this process, a silicon oxide film is embedded inside the trenches as shown in FIG. 7. This silicon oxide film embedded in the trenches forms the element isolation regions 20.

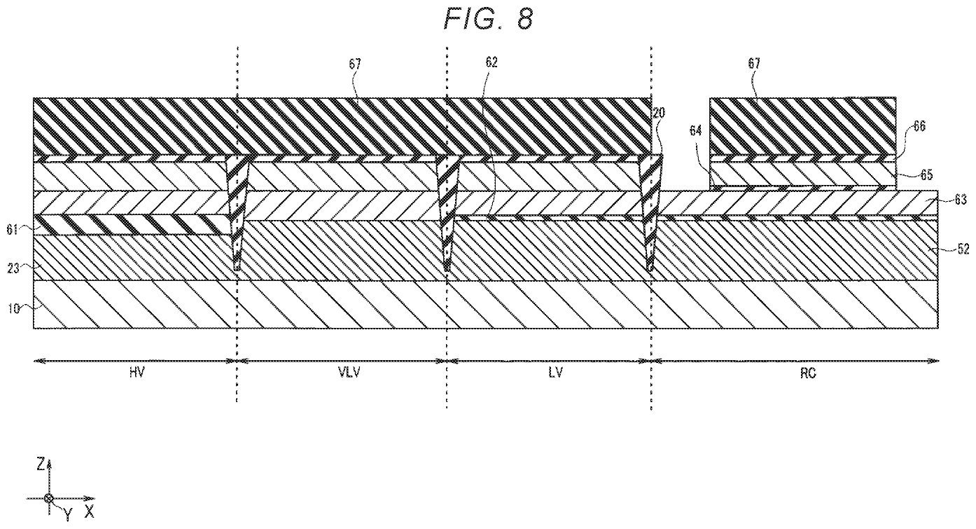

Subsequently, a resist 67 (photoresist film) is applied over the entire upper surface of the semiconductor substrate 10, and the resist 67 is patterned using a photolithography technique. At this time, the resist 67 is patterned so that the regions other than the active region corresponding to the resistance-capacitance elements RC remain fully covered. In the active region of the resistance-capacitance element, the region where the first conductive layer 42 is to be formed also remains covered with the resist 67, but regions outside where the first conductive layer 42 is to be formed are left exposed from the resist 67. Then, using an anisotropic etching technique, the silicon nitride film 66, the polysilicon film 65, and the silicon oxide film 64, which are exposed from the openings of the resist 67, are sequentially etched to expose the polysilicon film 63 at the bottom surface of the opening (see FIG. 8).

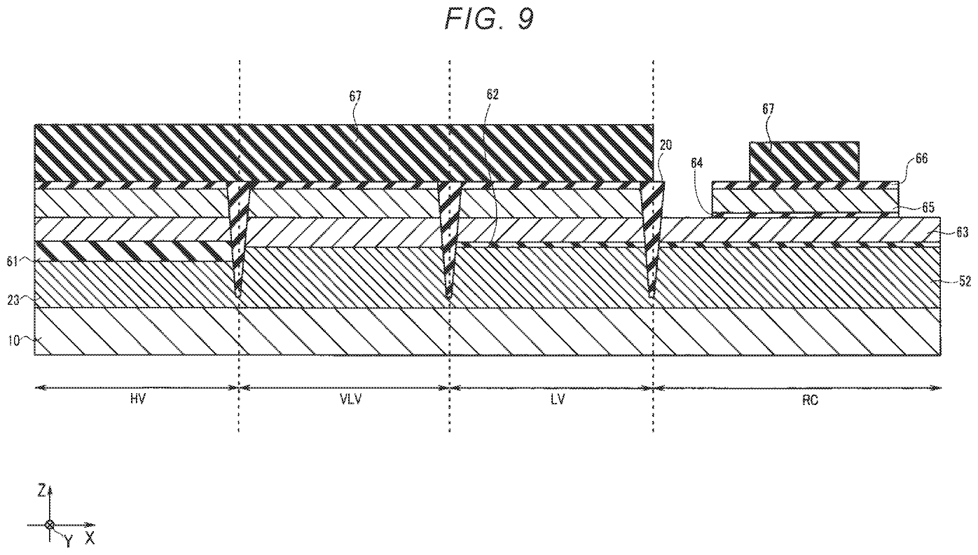

Then, the resist 67 covering the region where the first conductive layer 42 is to be formed in the active region of the resistance-capacitance element RC is slimmed (trimmed) to reduce the width of the resist 67 in the X direction. More specifically, in the active region of the resistance-capacitance element RC, the resist 67 is slimmed so that the resist 67 covers only the region which is a region surrounded by the region where the sidewall 48 is to be formed, and where the second conductive layer 46, the interlayer film 44, and the dielectric film 45 are formed. By the slimming process, the silicon nitride film 66 is exposed on the right and left sides of the resist 67 in the X direction, as shown in FIG. 9.

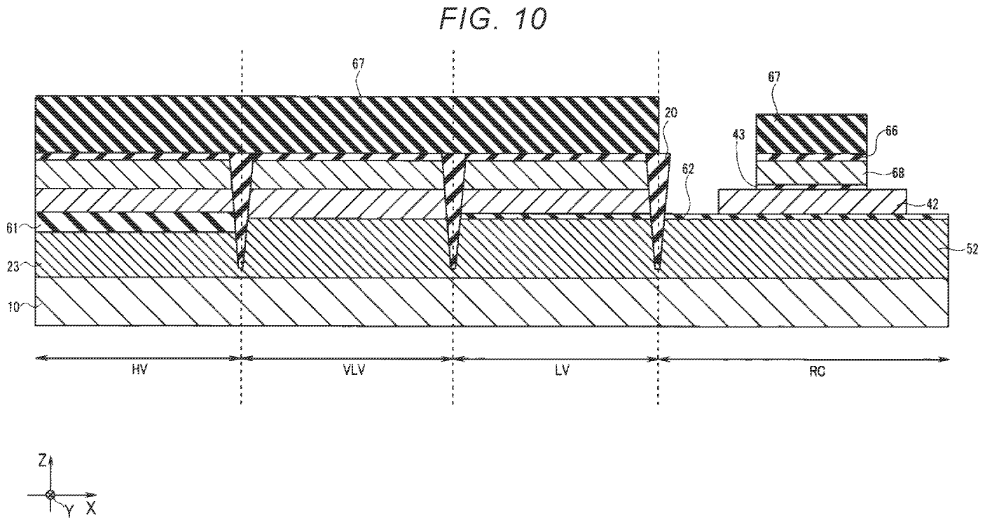

In this state, an anisotropic etching technique is then used to selectively remove the silicon nitride film 66, the polysilicon film 65, the silicon oxide film 64, and the polysilicon film 63, as shown in FIG. 10. The silicon nitride film 66, the polysilicon film 65, and the silicon oxide film 64 are etched using the resist 67 as a mask. That is, the portions of the silicon nitride film 66, the polysilicon film 65, and the silicon oxide film 64 without the covering of resist 67 are selectively removed. A dummy gate 68 made of the polysilicon film 65 is formed by the processes described with reference to FIGS. 8 to 10. The stopper insulating film 43 made of the silicon oxide film 64 is also formed.

Also, the polysilicon film 63 is etched at the same time as the polysilicon film 65 is etched. At this time, the polysilicon film 63 is etched using the polysilicon film 65 as a mask. That is, the portion over which the polysilicon film 65 is not formed (the portion other than the region where the resist 67 is formed in FIG. 8) is selectively removed and the first conductive layer 42 made of the polysilicon film 63 is formed.

Next, dummy gates 69 are formed for forming the gate electrodes 15 of the high voltage transistor HV, the low voltage transistor LV, and the very low voltage transistor VLV. In the active region of each transistor, a resist is patterned using a photolithography technique so positions where the gate electrodes 15, the interlayer films 12, and the gate dielectric films 13 are to be formed are covered with resist with the other positions not covered with resist after patterning. In this process, the active region of the resistance-capacitance element RC is covered with the resist. Then, using an anisotropic etching technique, the silicon nitride film 66, the polysilicon film 65, and the polysilicon film 63, which are exposed from the opening of the resist, are sequentially etched. As a result, the dummy gates 69 made of two layers of polysilicon films, that is, the polysilicon film 65 and the polysilicon film 63, are formed in each active region of the high voltage transistor HV, the low voltage transistor LV, and the very low voltage transistor VLV.

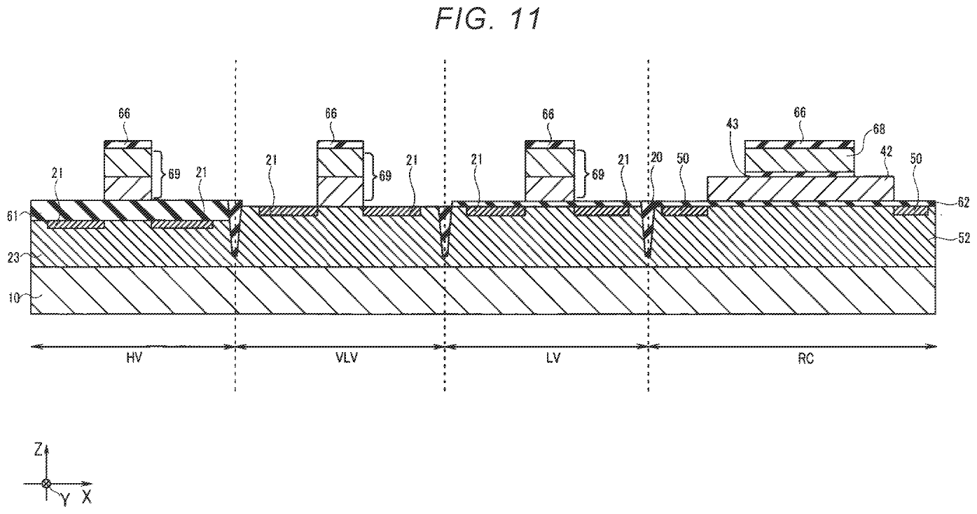

After removing the resist, an ion implantation technique is used to implant impurities into the semiconductor substrate 10 (very shallow regions from the upper surface) on the left and right sides of the dummy gates 68 and 69 in the X direction and the LDD region 21 and the first impurity region 50 are formed (see FIG. 11). If the transistor to be formed is an NMOS transistor, n-type impurities such as arsenic (As) or phosphorus (P) are implanted. If the transistor to be formed is a PMOS transistor, p-type impurities such as boron (B) are implanted. The active region of the resistance-capacitance element RC can be implanted with the same impurity as that implanted into the LDD region 21 of any one of the high voltage transistor HV forming region, the low voltage transistor LV forming region, or the very low voltage transistor VLV forming region.

Subsequently, a silicon oxide film is conformally formed on the entire upper surface of the semiconductor substrate 10 using a CVD technique or the like. This silicon oxide film is then etched back using an anisotropic etching technique to leave sidewalls covered with remaining portions of the silicon oxide film. Specifically, the sidewall 16 is formed on the side surfaces of the dummy gates 69, the sidewall 48 is formed on the side surfaces of the dummy gate 68, and the sidewall 49 is formed on the side surfaces of the first conductive layer 42.

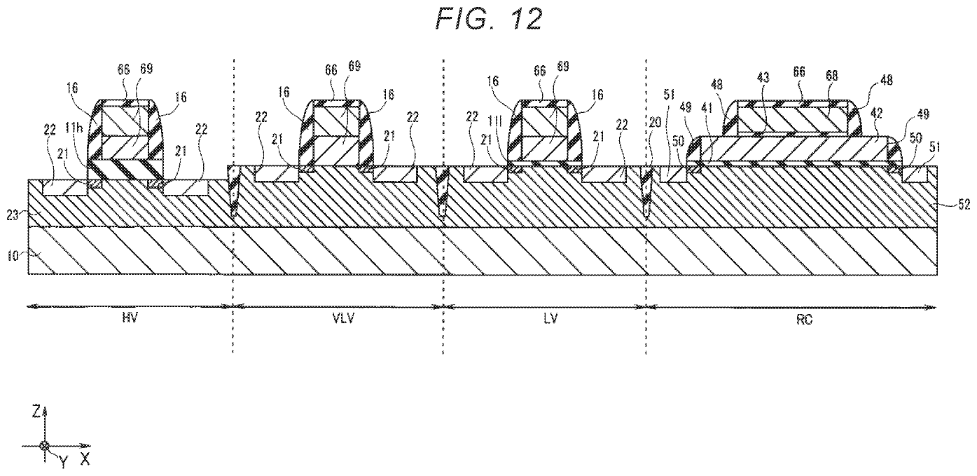

Using an ion implantation technique, impurities are implanted into the semiconductor substrate 10 to the left and right sides of the sidewalls 16 and 49 in the X direction to form the source and drain regions 22 and the second impurity regions 51 (see FIG. 12). If the transistor to be formed is an NMOS transistor, n-type impurities such as arsenic (As) or phosphorus (P) are implanted. If the transistor to be formed is a PMOS transistor, p-type impurities such as boron (B) are implanted. The active region of the resistance-capacitance element RC is implanted with the same impurity as that implanted into the source and drain regions 22 of any one of the high voltage transistor HV forming region, the low voltage transistor LV forming region, and the very low voltage transistor VLV forming region.

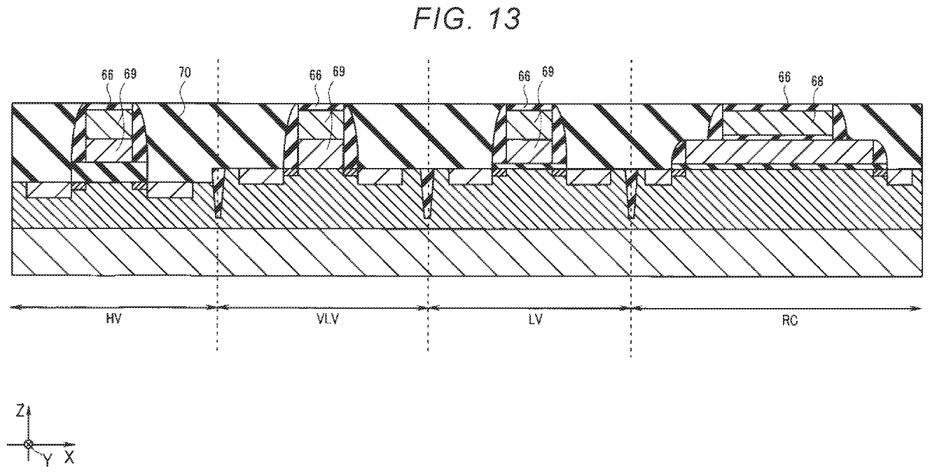

Next, a silicon oxide film 70 is formed on the entire upper surface of the semiconductor substrate 10 using a CVD technique or the like. Using a CMP technique or the like, portions of the silicon oxide film 70 above the upper surface position of the silicon nitride film 66 are removed using the silicon nitride film 66 as a stopper, as shown in FIG. 13.

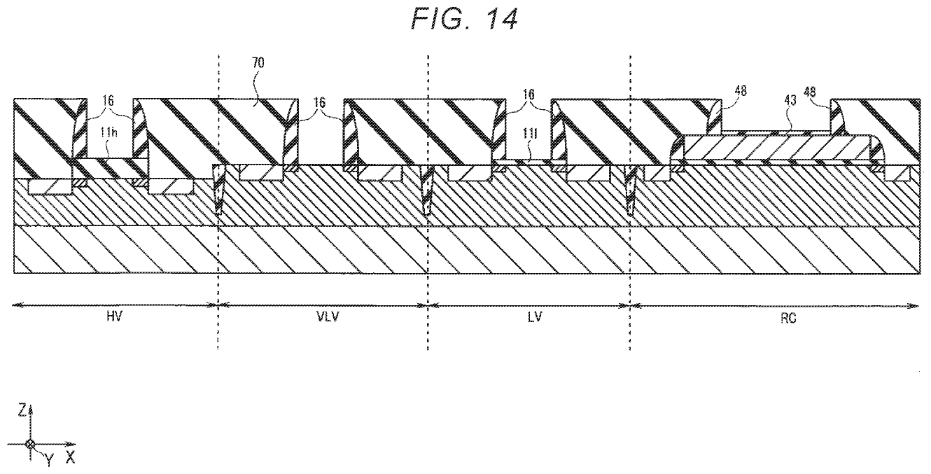

Subsequently, the silicon nitride film 66 is removed by an isotropic etching technique using a chemical solution (for example, hot phosphoric acid) capable of selectively removing the silicon nitride film. In some examples, silicon nitride film 66 may be removed by anisotropic etching using remaining portions of silicon oxide film 70 as a mask. Then, the dummy gates 68 and 69 are then removed by an isotropic etching technique using a chemical solution (for example, hydrofluoric nitric acid) capable of selectively removing polysilicon. In other examples, dummy gates 68 and 69 may also be removed by anisotropic etching using the silicon oxide film 70 as a mask. This two-step removal process forms trenches or unfilled space inside the sidewalls 16 and 48, as shown in FIG. 14.

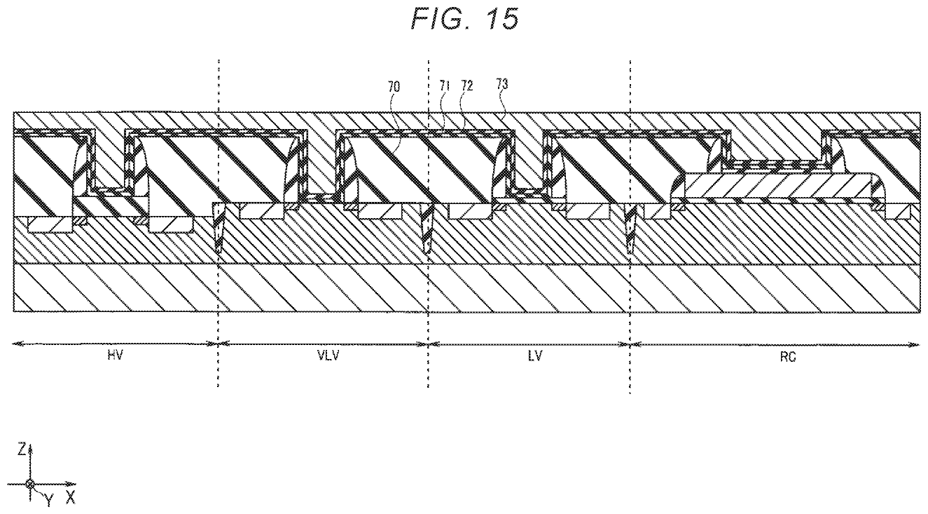

Next, a silicon oxide film 71 is formed on the entire upper surface of the semiconductor substrate 10 using a CVD technique or the like. Subsequently, an insulating film 72 of a high-k dielectric material (for example, hafnium silicate (HfSiO)) is formed on the surface of the silicon oxide film 71 using a CVD technique or the like. In this context, “high-k” refers to the value of the dielectric constant (k). Subsequently, a conductive film 73 of a metal material (for example, tungsten (W) or aluminum (Al)) is formed on the surface of the insulating film 72 by using a CVD technique or the like. The structure as shown in FIG. 15 is formed by three film formation process in sequence.

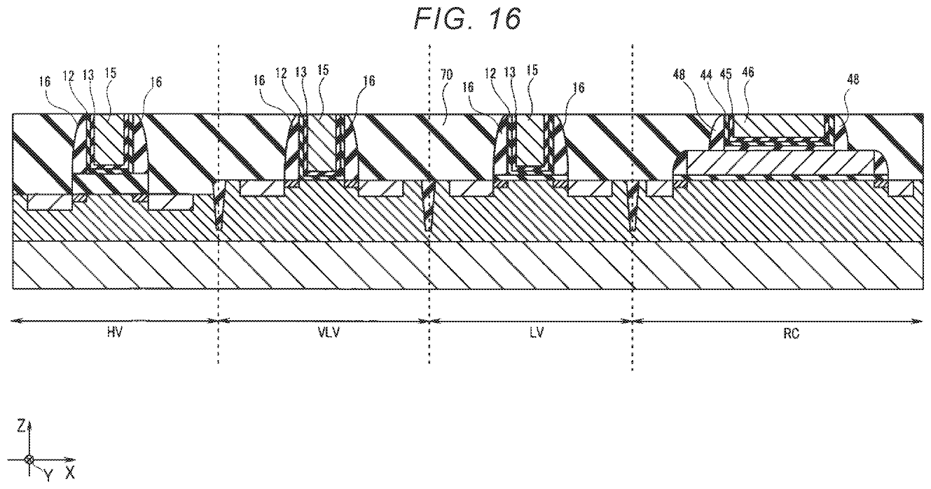

Then, using a CMP technique or the like, upper portions of the conductive film 73, the insulating film 72, and the silicon oxide film 71 are removed using the silicon oxide film 70 as a stopper to form the structure shown in FIG. 16. Specifically, a gate electrode 15 (made of the conductive film 73) is in a trench formed in the sidewalls 16, and gate dielectric film 13 (made of the insulating film 72) covers the lower surface and side surfaces of the gate electrode 15, and the interlayer film 12 (made of the silicon oxide film 71) covers the lower surface and side surfaces of the gate dielectric film 13. The second conductive layer 46 (made of the conductive film 73) is formed inside a trench formed in the sidewalls 48, and the dielectric film 45 (made of the insulating film 72) covers the lower surface and side surfaces of the second conductive layer 46, and the interlayer film 44 (made of the silicon oxide film 71) covers the lower surface and side surfaces of the dielectric film 45.

Subsequently, a silicon oxide film is formed on the entire upper surface of the semiconductor substrate 10 using a CVD technique or the like to cover both the upper surface of the gate electrode 15 and the upper surface of the second conductive layer 46. The interlayer insulating film 30 comprises this silicon oxide film and the previously formed silicon oxide film 70. Then, using a photolithography technique and an anisotropic etching technique, holes (contact holes) are formed penetrating the interlayer insulating film 30 to reach the source and drain regions 22 of the semiconductor substrate 10. At the same time, a contact hole that reaches the gate electrode 15, a contact hole that reaches the second impurity region 51 of the semiconductor substrate 10, a contact hole that reaches the first conductive layer 42, and a contact hole that reaches the second conductive layer 46 are also formed in the interlayer insulating film 30. Finally, the contact holes are embedded (filled) with a metal material using a CVD technique or the like to form the contact plugs 31 and 32 and the first to third contact plugs 53 to 55. By executing the series of procedures described above, the semiconductor device 1 having the structure shown in FIG. 1 is formed.

Thus, in the semiconductor device of the present embodiment, the resistance-capacitance element RC is formed by stacking the semiconductor substrate 10, the first insulating film 41, the first conductive layer 42, the second insulating film 47, and the second conductive layer 46. The first conductive layer 42 is made of polysilicon, and the second conductive layer 46 is made of a metal material. With such a configuration, the resistance-capacitance element RC can be used as a first-type capacitor by using the three layers of the semiconductor substrate 10, the first insulating film 41, and the first conductive layer 42. Also, the resistance-capacitance element RC can be used as a second-type capacitor by using the three layers of the first conductive layer 42, the second insulating film 47, and the second conductive layer 46. Also, the first conductive layer 42 made of polysilicon has a higher resistance than wiring made of a metal material, and thus, the first conductive layer 42 can be used as a resistance element. By stacking the first-type capacitor and the second-type capacitor and forming at least one electrode of a capacitor from polysilicon, the same electrode can be used as a resistor according to design needs. Therefore, in the semiconductor device of an embodiment, the capacitor, and the resistance element can be located with good area (die area) utilization efficiency.

Further, according to the method for manufacturing a semiconductor device of the present embodiment, when manufacturing the MOS transistors (the high voltage transistor HV, the low voltage transistor LV, and the very low voltage transistor VLV), after forming the dummy gate 69 with polysilicon, the first conductive layer 42, the second insulating film 47, and the second conductive layer 46 of the resistance-capacitance element RC are formed by using a process of removing the dummy gate 69 and replacing the dummy gate 69 with a conductive film using a metal material. Specifically, in the MOS transistor, polysilicon films 63 and 65 are sequentially deposited to form the dummy gate 69 having a two-layer structure. After depositing the polysilicon film 63, in the resistance-capacitance element RC, the silicon oxide film 64 is deposited, and then the polysilicon film 65 is deposited to form the dummy gate 68 of the polysilicon film 65 alone. In the process of collectively removing the two layers of polysilicon films 63 and 65 forming the dummy gate 69 of the MOS transistor, the silicon oxide film 64 serves as an etching stopper for the dummy gate 68 of the resistance-capacitance element RC, and only the upper polysilicon film 65 is removed and the underlying polysilicon film 63 remains. Also, the silicon oxide film 64 remains without being removed. That is, using the process of forming a MOS transistor, a resistance-capacitance element RC in which a resistance element and two capacitors are stacked can be formed. Therefore, according to the method for manufacturing the semiconductor device of the embodiment, a CMOS transistor, a capacitor, and a resistance element can be efficiently manufactured.

In the semiconductor device shown in FIG. 1, the width of the second conductive layer 46 of the resistance-capacitance element RC is narrower than the width of the first conductive layer 42 of the resistance-capacitance element RC, and the first conductive layer 42 and the second conductive layer 46 thus form a stepped structure, but in other examples the width of the first conductive layer 42 and the width of the second conductive layer 46 may be made the same and thus the stepped structure need not be formed in each instance.

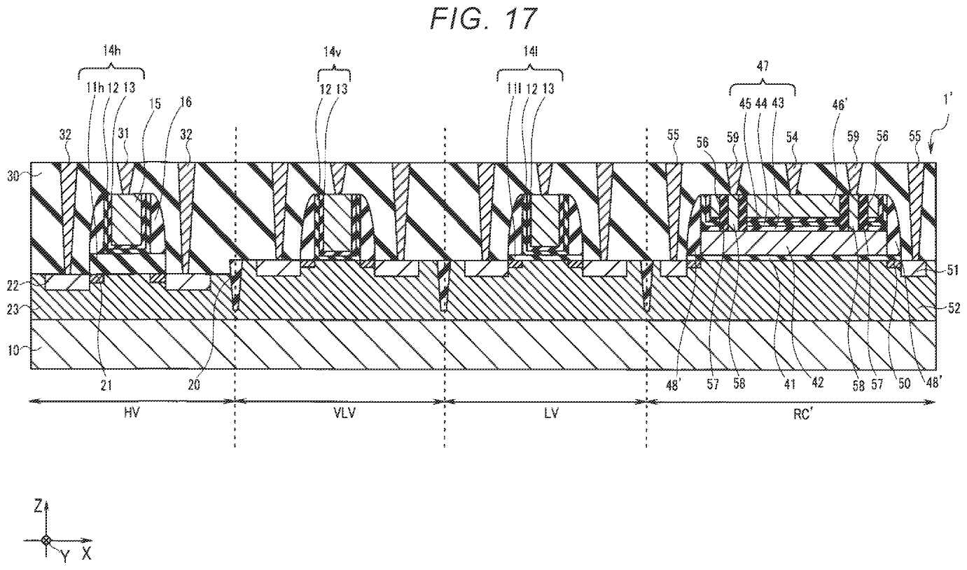

FIG. 17 is a cross-sectional view schematically illustrating another structure of a semiconductor device according to an embodiment. The semiconductor device 1′ shown in FIG. 17 differs from the semiconductor device 1 shown in FIG. 1 in the structure of the resistance-capacitance element RC′. The structures of the high voltage transistor HV, the low voltage transistor LV, and the very low voltage transistor VLV are the same as those of the semiconductor device 1 shown in FIG. 1. The components that are the same as those of the semiconductor device 1 shown in FIG. 1 are denoted by the same reference symbols and differences are described below.

In a resistance-capacitance element RC′ of the semiconductor device 1′ shown in FIG. 17, the first conductive layer 42 is formed on the semiconductor substrate 10 in an active region (with the first insulating film 41 interposed therebetween). A second conductive layer 46′ is formed on the first conductive layer 42 with the stopper insulating film 43, the interlayer film 44, and the dielectric film 45 interposed therebetween. The width (dimension in the X direction) of the second conductive layer 46′ is the same as the width of the first conductive layer 42. A sidewall 48′ covers the outer surface of the interlayer film 44 formed on the side surface of the first conductive layer 42 and the side surface of the second conductive layer 46′, that is, the surface of the interlayer film 44 opposite to the surface in contact with the dielectric film 45. The interlayer insulating film 30 covers the upper surface of the second conductive layer 46′, the sidewall 48′, and the second impurity regions 51.

A through via hole 56 is formed in the second conductive layer 46′. In FIG. 17, two through via holes 56 are shown formed. Each through via hole 56 is a hole penetrating from the upper surface of the second conductive layer 46′ to the upper surface of the first conductive layer 42. On the inner wall of the through via hole 56, a spacer insulating film 57 made of, for example, a silicon oxide film is formed. A fourth contact plug 58 made of a conductive material is formed inside the spacer insulating film 57. A fifth contact plug 59 is formed above the fourth contact plug 58 to provide electrical connection to a later-formed wiring layer above interlayer insulating film 30. The first conductive layer 42 can be electrically connected to this wiring layer by the fifth contact plug 59 and the fourth contact plug 58.

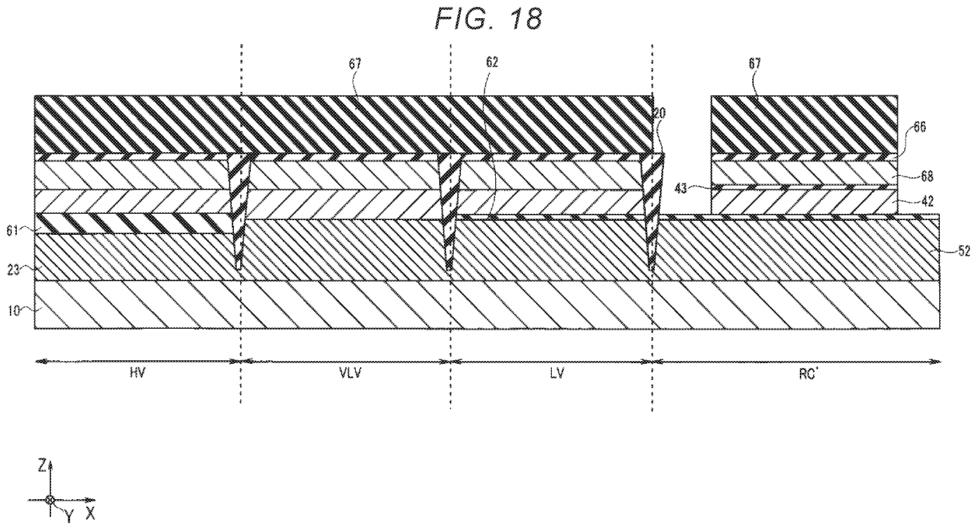

A method for manufacturing the semiconductor device 1′ shown in FIG. 17 will be described. The processes from the formation of the well diffusion layers 23 and 52 to the formation of the element isolation region 20 are the same as those shown in FIGS. 2 to 7 for the semiconductor device 1. The manufacturing method after the formation of the element isolation region 20 will be described with reference to FIGS. 18 to 26. After forming up to the element isolation region 20 as shown in FIG. 7, the resist 67 is initially applied to the entire upper surface of the semiconductor substrate 10, and then patterned as depicted in FIG. 18 using a photolithography technique. Then, using an anisotropic etching technique, the silicon nitride film 66, the polysilicon film 65, the silicon oxide film 64, and the polysilicon film 63, which are exposed by the patterned resist 67, are sequentially etched to expose the silicon oxide film 62 at the bottom surface of the opening (see FIG. 18). By this etching, the dummy gate 68 is formed from the polysilicon film 65, the stopper insulating film 43 is formed from the silicon oxide film 64, and the first conductive layer 42 is formed from the polysilicon film 63.

Next, the dummy gates 69 are formed for forming the gate electrodes 15 of the high voltage transistor HV, the low voltage transistor LV, and the very low voltage transistor VLV. In the active region of each transistor, a resist is patterned so all positions other than where the gate electrodes 15, the interlayer films 12, and the gate dielectric films 13 are to be formed are left uncovered by the patterned resist. In this process, the active region of the resistance-capacitance element RC′ is covered with the resist. Then, using an anisotropic etching technique, the portions of the silicon nitride film 66, the polysilicon film 65, and the polysilicon film 63, which are exposed by the patterned resist, are sequentially etched. As a result, the dummy gates 69 made of two layers of polysilicon films (polysilicon film 65 and polysilicon film 63) are formed in each active region of the high voltage transistor HV, the low voltage transistor LV, and the very low voltage transistor VLV.

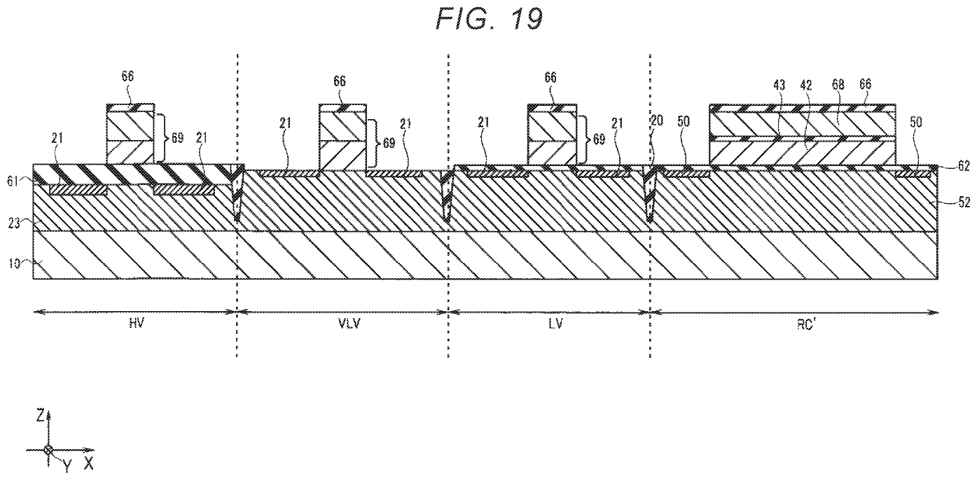

After removing the resist, an ion implantation technique is used to implant impurities into the semiconductor substrate 10 (very shallow regions from the upper surface) on the left and right sides of the dummy gates 68 and 69 in the X direction to form the LDD regions 21 and the first impurity regions 50 (see FIG. 19). The same impurity as that implanted into the LDD region 21 of any one of the high voltage transistor HV forming region, the low voltage transistor LV forming region, and the very low voltage transistor VLV forming region is implanted into the active region of the resistance-capacitance element RC′.

Subsequently, a silicon oxide film is conformally formed on the entire upper surface of the semiconductor substrate 10 using a CVD technique or the like. Next, this silicon oxide film is etched back using an anisotropic etching technique such as RIE to leave portions of the silicon oxide film on sidewalls of dummy gates 68 and 69 and the like. Specifically, the sidewalls 16 on the side surfaces of the dummy gate 69, and the sidewalls 48′ on the side surfaces of the dummy gate 68 and the first conductive layer 42 are formed in this process.

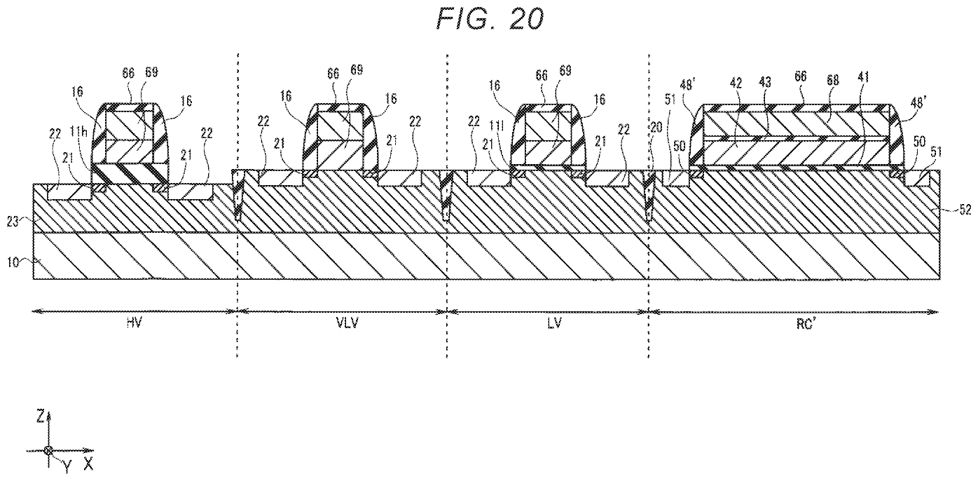

Using an ion implantation technique, impurities are implanted into the semiconductor substrate 10 on the left and right sides of the sidewalls 16 and 48′ in the X direction to form the source and drain regions 22 and the second impurity regions 51 (see FIG. 20). The active region of the resistance-capacitance element RC′ can be implanted with the same impurity as that implanted into the source and drain region 22 of any one of the high voltage transistor HV forming region, the low voltage transistor LV forming region, and the very low voltage transistor VLV forming region.

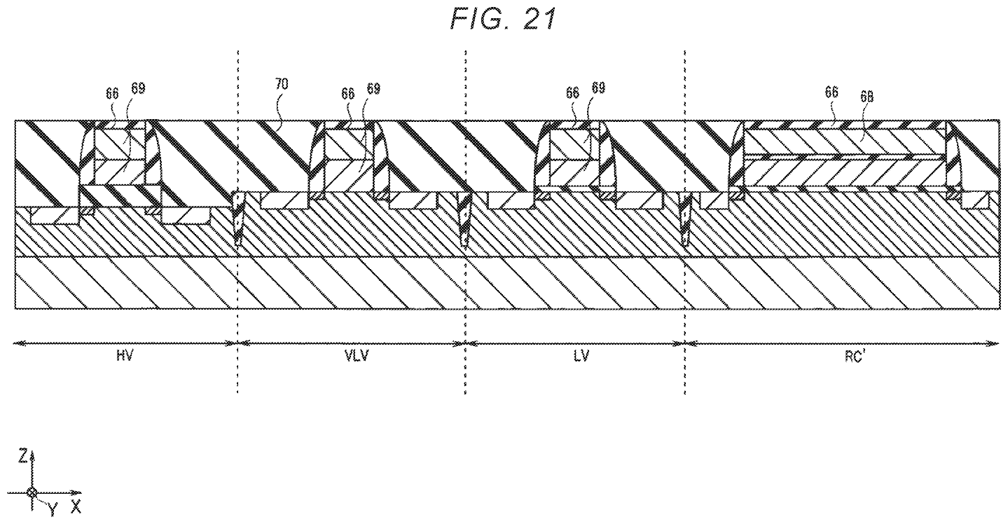

Next, the silicon oxide film 70 is formed on the entire upper surface of the semiconductor substrate 10 using a CVD technique or the like. Using a CMP technique or the like, upper portions of the silicon oxide film 70 are removed using the silicon nitride film 66 as a stopper, as shown in FIG. 21.

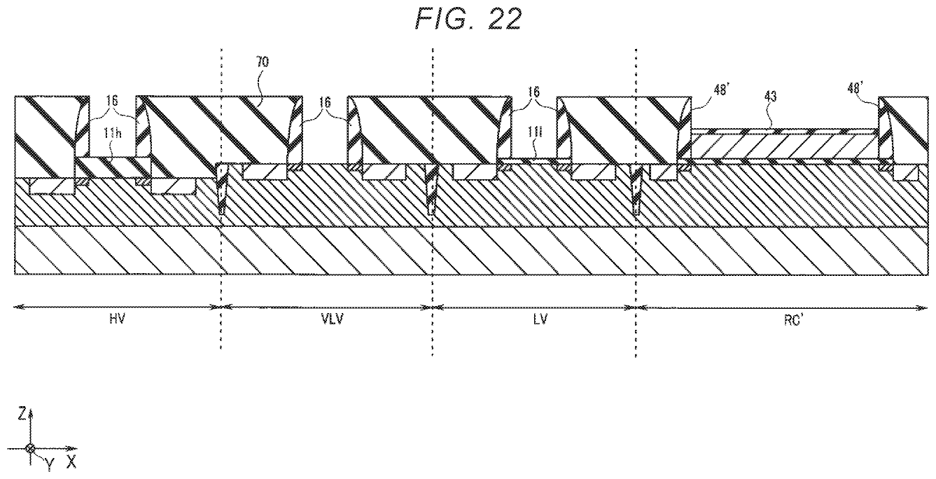

Subsequently, the silicon nitride film 66 is removed by an isotropic etching technique using a chemical solution (for example, hot phosphoric acid). In some examples, silicon nitride film 66 may be removed by anisotropic etching using the silicon oxide film 70 as a mask. Then, the dummy gates 68 and 69 are removed by an isotropic etching technique using a chemical solution (for example, hydrofluoric nitric acid). In other examples, dummy gates 68 and 69 may instead be removed by anisotropic etching using the silicon oxide film 70 as a mask. This two-step removal process forms trenches or unfilled space inside the sidewalls 16 and 48′ as shown in FIG. 22.

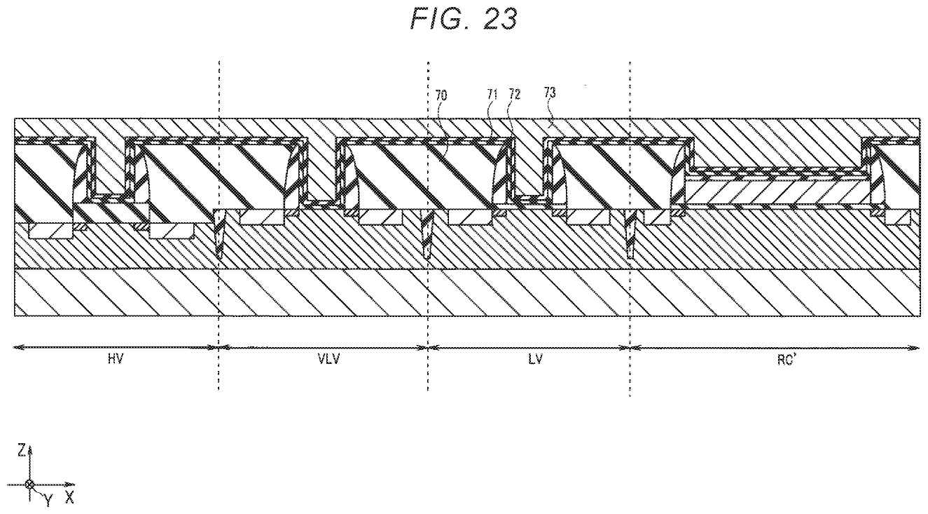

Next, the silicon oxide film 71 is formed on the entire upper surface of the semiconductor substrate 10 using a CVD technique or the like. Subsequently, the insulating film 72 using a high-k dielectric material (for example, hafnium silicate (HfSiO)) is formed on the surface of the silicon oxide film 71 using a CVD technique or the like. Subsequently, the conductive film 73 using a metal material (for example, tungsten (W) or aluminum (Al)) is formed on the surface of the insulating film 72 by using a CVD technique or the like. A structure as shown in FIG. 23 is formed by these three film formation processes in sequence.

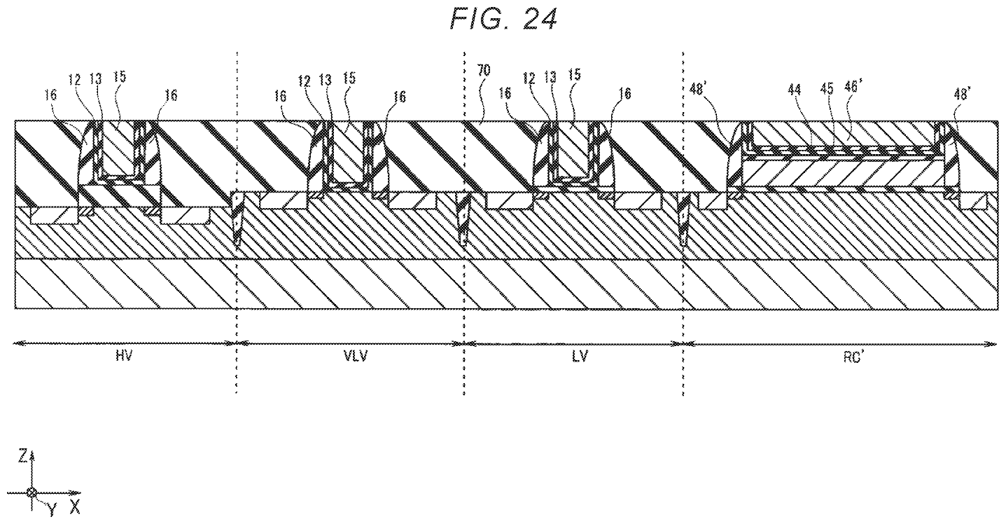

Then, upper portions of the conductive film 73, the insulating film 72, and the silicon oxide film 71 are removed using a CMP technique or the like using the silicon oxide film 70 as a stopper to form the structure shown in FIG. 24. Specifically, the gate electrode 15 (made of the conductive film 73) is formed in a trench formed in the sidewall 16, and the gate dielectric film 13 (made of the insulating film 72) covers the lower surface and side surfaces of the gate electrode 15, and the interlayer film 12 (made of the silicon oxide film 71) covers the lower surface and side surfaces of the gate dielectric film 13. Also, the second conductive layer 46′ (made of the conductive film 73) is formed in the trench formed in the sidewall 48′, the dielectric film 45 (made of the insulating film 72) covers the lower surface and side surfaces of the second conductive layer 46′, and the interlayer film 44 (made of the silicon oxide film 71) covers the lower surface and side surfaces of the dielectric film 45.

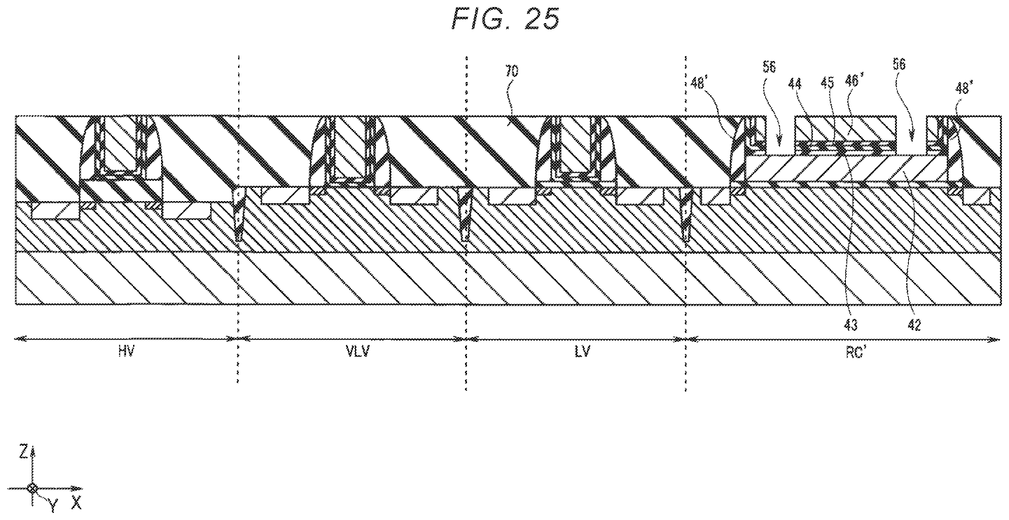

Subsequently, as shown in FIG. 25, a photolithography technique and an anisotropic etching technique are used to form the through via hole 56 through each layer of the second conductive layer 46′, the dielectric film 45, the interlayer film 44, and the stopper insulating film 43 from the upper surface of the second conductive layer 46′ to reach the upper surface of the first conductive layer 42.

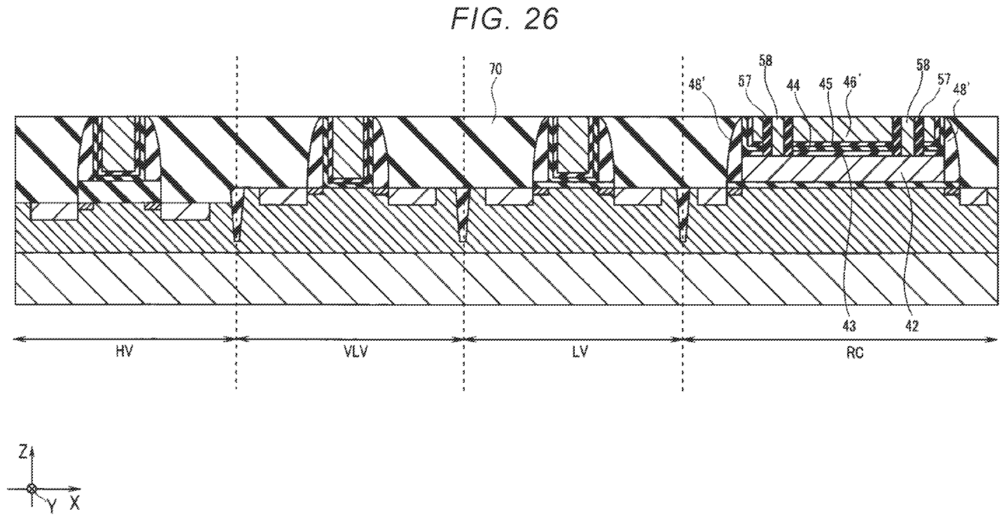

Then, a spacer insulating film 57 made of, for example, a silicon oxide film is formed on the inner wall of the through via hole 56 using a CVD technique and an anisotropic etching technique. At this time, the silicon oxide film formed on the bottom surface of the through via hole 56 is removed so that the first conductive layer 42 is exposed at the bottom surface of the through via hole 56. Then, using a CVD technique or a sputtering technique a conductive material (e.g., a metal) such as tungsten (W) or aluminum (Al) is filled into the through via hole 56 to form the fourth contact plug 58 as shown in FIG. 26.

A silicon oxide film can then be formed on the entire upper surface of the semiconductor substrate 10 using a CVD technique or the like to cover the upper surface of the gate electrode 15 and the upper surface of the second conductive layer 46′. The interlayer insulating film 30 is formed by this silicon oxide film and the previously formed silicon oxide film 70. Then, using a photolithography technique and an anisotropic etching technique, holes (contact holes) are formed penetrating the interlayer insulating film 30 to reach the source and drain regions 22 of the semiconductor substrate 10. At the same time, a contact hole that reaches the gate electrode 15, a contact hole that reaches the second impurity region 51 of the semiconductor substrate 10, a contact hole that reaches the fourth contact plug 58, and a contact hole that reaches the second conductive layer 46′ are formed in the interlayer insulating film 30. Finally, the contact holes are embedded (filled) with a metal material using a CVD technique or the like to form the contact plugs 31 and 32, the first contact plug 53, the second contact plug 54, and the fifth contact plug 59. The semiconductor device 1′ having the structure shown in FIG. 17 can thus be formed by executing the series of procedures described above.

In the semiconductor device 1′, since the width of the second conductive layer 46′ is equal to the width of the first conductive layer 42, it is possible to increase the electrode area of the second-type capacitor, which is formed by the three layers of the first conductive layer 42, the second insulating film 47, and the second conductive layer 46′. Therefore, the capacitance of the second-type capacitor can be increased. Moreover, since the through via hole 56 can be formed at any position on the upper surface of the second conductive layer 46′, the degree of freedom in circuit design of the semiconductor device 1′ is increased.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a transistor including:
a gate insulating film on an upper surface of a semiconductor substrate and including a dielectric film, and
a gate electrode on an upper surface of the gate insulating film, the gate electrode being a metal material; and
a resistance-capacitance element including:
a first insulating film on the upper surface of the semiconductor substrate,
a first conductive layer on an upper surface of the first insulating film,
a second insulating film on an upper surface of the first conductive layer,
a third insulating film on an upper surface of the second insulating film, and
a second conductive layer on an upper surface of the third insulating film, wherein
the third insulating film includes the dielectric film of the gate insulating film,
the second conductive layer is the same metal material as the gate electrode, and
the first conductive layer is a conductive material having a higher resistance than the metal material of the second conductive layer.

2. The semiconductor device according to claim 1, wherein
the conductive material is polysilicon, and
the second insulating film is a silicon oxide film.

3. The semiconductor device of claim 1, wherein the transistor and the resistance-capacitance element are electrically isolated from one another by an element isolation region provided in the semiconductor substrate.

4. The semiconductor device according to claim 1, wherein the resistance-capacitance element further includes:
a first contact plug electrically connected to the first conductive layer,
a second contact plug electrically connected to the second conductive layer, and
a third contact plug electrically connected to the semiconductor substrate.

5. The semiconductor device according to claim 4, wherein
a surface area of the second conductive layer is smaller than a surface area of the first conductive layer, and
the first contact plug is connected to a portion of the upper surface of the first conductive layer not covered by the second conductive layer.

6. The semiconductor device according to claim 4, wherein the first contact plug is in a through via hole that penetrates the second conductive layer, the second insulating film, and the third insulating film and reaches the first conductive layer.

7. The semiconductor device according to claim 1, wherein an uppermost surface of the gate electrode and an uppermost surface of the second conductive layer are at a same height from the semiconductor substrate.

8. The semiconductor device according to claim 1, wherein the dielectric film is a high-k dielectric material.

9. The semiconductor device according to claim 1, wherein the dielectric film is hafnium silicate.

10. The semiconductor device according to claim 9, wherein
the metal material is tungsten or aluminum, and
the conductive material is polysilicon.

11. The semiconductor device according to claim 1, wherein
the metal material is tungsten or aluminum, and
the conductive material is polysilicon.

12. A semiconductor device, comprising:
a semiconductor substrate;
a high voltage transistor in a first region of the semiconductor substrate;
a low voltage transistor in a second region of the semiconductor substrate;
a very low voltage transistor in a third region of the semiconductor substrate;
a resistance-capacitance element in a fourth region of the semiconductor substrate, the resistance-capacitance element being configurable as a first-type capacitor, a second-type capacitor, and a resistor; and
an interlayer insulator covering the high voltage transistor, the low voltage transistor, the very low voltage transistor, and the resistance-capacitance element, wherein
each of the transistors includes a gate electrode, a first high-k dielectric film on bottom and side surfaces of the gate electrode, and a first interlayer film on bottom and side surfaces of the first high-k dielectric film,
the high voltage transistor having a gate oxide layer of a first thickness between the bottom surface of the gate electrode and the semiconductor substrate, and
the low voltage transistor having a gate oxide layer of a second thickness, less than the first thickness, between the bottom surface of the gate electrode and the semiconductor substrate.

13. The semiconductor device according to claim 12, wherein the resistance-capacitance element has:
a first insulating film on a surface of the semiconductor layer, the first insulating film having the second thickness and being a same material as the gate oxide film of the low voltage transistor;
a first conductive layer on the first insulating film and formed of polysilicon;
a stopper layer on the first conductive layer, the stopper layer being formed of insulator material;
a second interlayer film on the stopper layer, the second interlayer film being formed of the same material as the first interlayer film;
a second high-k dielectric film on the second interlayer film, the second high-k dielectric film being formed of the same material as the first high-k dielectric film; and
a second conductive layer on the second high-k dielectric film, the second conductive layer being formed of the same material as the gate electrode.

14. The semiconductor device according to claim 13, wherein the second high-k dielectric film and the second interlayer film are on a sidewall of the second conductive layer.

15. The semiconductor device according to claim 13, wherein a planar area of the second conductive layer is less than a planar area of the first conductive layer.

16. The semiconductor device according to claim 13, further comprising:
a plurality of contacts extending vertically in the interlayer insulator to an upper surface of the interlayer insulator.

17. The semiconductor device according to claim 13, wherein an uppermost surface of each gate electrode is at a same height as an uppermost surface of the second conductive layer.

18. A method for manufacturing a semiconductor device, the method comprising:
forming a first insulating film on an upper surface of a semiconductor substrate;
forming a first conductive film made of a conductive material on an upper surface of the first insulating film;
forming a second insulating film made of an insulating material on a portion of an upper surface of the first conductive layer;
forming a second conductive film made of the conductive material on an upper surface of the first conductive film and an upper surface of the second insulating film;
forming a first trench extending from the upper surface of the second conductive film to a predetermined depth in the semiconductor substrate at a position including a peripheral edge of the second insulating film;
embedding an element isolation insulating film in the first trench;
processing the second conductive film, the second insulating film, and the first conductive film in a first region of the semiconductor substrate into a predetermined shape of a resistor wiring or capacitor electrode;
processing the second conductive film and the first conductive film in a second region of the semiconductor substrate into a predetermined shape of a gate electrode;
forming sidewalls made of insulating material on the processed second conductive film, second insulating film, and first conductive film;
forming a second trench inside the sidewalls by removing the conductive material inside the sidewalls using conditions having a high selectivity with respect to the insulating material;
forming a dielectric film made of a high-k dielectric material on an inner wall surface of the second trench; and
embedding a third conductive film made of a metal material in the second trench to form the gate electrode and the resistor wiring or capacitor electrode on a surface of the dielectric film.

19. The method according to claim 18, further comprising:
processing the second conductive film to have a width less than a width of the first conductive film in the first region; and
forming a contact plug connected to an upper surface of the resistor wiring or capacitor electrode exposed by the processing of the second conductive film.

20. The method according to claim 18, wherein a width of the second conductive film is equal to a width of the first conductive film in the first region after the second conductive film, the second insulating film, and the first conductive film are processed into the predetermined shape of the resistor wiring or capacitor electrode;
forming a through via hole that penetrates the third conductive film, the high dielectric film, and the second insulating film and reaches an upper surface of the first conductive film; and
forming a contact plug in the through via hole.
